(19) United States
(12) Patent Application Publication
(10) Pub. No.: US 2008/0108270 A1
(43) Pub. Date: May 8, 2008

(54) METHOD OF MANUFACTURING A WHITE LIGHT EMITTING ORGANIC EL DEVICE

(75) Inventor: Toshio HAMA, Matsumoto City (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD., Kawasaki-ku (JP)

(21) Appl. No.: 11/876,170

(22) Filed: Oct. 22, 2007

(30) Foreign Application Priority Data
Oct. 24, 2006 (JP) 2006-288825

(51) Int. Cl. H01J 9/02

(52) U.S. Cl. 445/24

(57) ABSTRACT

A method of manufacturing a white light emitting organic EL device is disclosed. A white light emitting organic EL device having a plurality of organic EL layers each emitting different color light from each other without an increase in a driving voltage is readily fabricated. The method manufactures a white light emitting organic EL device having at least a reflective electrode, a first organic EL layer that emits light in a first color, an intermediate electrode unit, a second organic EL layer that emits light in a second color different from the first color, and a second transparent electrode in this order. The reflective electrode is of the same polarity as the second transparent electrode, and the intermediate electrode unit is of opposite polarity to the reflective electrode and the second transparent electrode. The method includes steps of (1) preparing a first organic light emitting unit including the reflective electrode and the first organic EL layer, (2) preparing a second organic light emitting unit including the second transparent electrode and the second organic EL layer, (3) preparing an intermediate electrode unit including a first transparent electrode on both sides thereof, and (4) disposing the intermediate electrode unit between the first organic light emitting unit and the second organic light emitting unit such that each of the first organic EL layer and the second organic EL layer opposes the intermediate electrode unit.

### CROSS REFERENCE TO RELATED APPLICATIONS

This application claims priority from Japanese application Serial No. JP 2006-288825, filed on Oct. 24, 2006, the entire contents of which are incorporated herein by reference.

### BACKGROUND OF THE INVENTION

A. Field of the Invention

The present invention relates to a method of manufacturing a white light emitting organic EL (electroluminescent) device. Organic EL devices exhibit high definition and excellent visibility, and can be applied to a broad range of display panels in mobile terminals, industrial instruments, domestic TV sets, and the like.

B. Description of the Related Art

A type of known light emitting device used in display units is an organic EL light emitting device having a layered structure of thin films of organic compounds. An organic EL light emitting device is a thin film self-emitting device that exhibits favorable features, including low driving voltage, high resolution, and wide visible angle, and thus it has been extensively studied for its practical application.

An organic EL light emitting device has a structure including at least an organic light emitting layer provided between an anode and a cathode. An organic EL light emitting device also includes, if necessary, one or more of a hole injection layer, a hole transport layer, an electron transport layer, and an electron injection layer. On application of a voltage between the anode and the cathode, holes and electrons are injected into the organic EL light emitting device. The injected holes and electrons recombine in the organic light emitting layer, exciting organic EL substances in the organic light emitting layer to a high energy state. The organic EL substances emit light upon transition from the high energy state to the ground state.

A display panel includes multiple pixels arranged in a matrix form. The matrix of pixels can be driven by various methods, among which a so-called simple matrix drive has a relatively simple construction and is frequently employed. In the display panel of the simple matrix drive, anodes and cathodes are strips arranged in rows and columns, the anodes and cathodes being aligned orthogonal to each other. Individual signal is displayed at a pixel at which a strip of anode and a strip of cathode intersect.

Methods for obtaining full color are focused at present on a method to combine a wide range of emission spectrum (white light, for example) and color filters. Many white light emitting organic EL devices have been proposed. Japanese Patent No. 3366401, for example, discloses provision of two light emitting layers for two different colors between an anode and a cathode. Japanese Unexamined Patent Application Publication No. 2003-45676 discloses a method to obtain white light in which a plurality of organic light emitting units are arranged in series through equipotential surfaces therebetween. Japanese Patent No. 3189438 discloses that by stacking organic EL light emitting devices that emit the same color light and are connected in parallel, the current density in the light emitting devices is reduced and thus the life time of the device is lengthened.

Japanese Unexamined Patent Application Publication No. 2004-327248 (corresponding to US Patent Application Publication No. US2004/0232828A1) discloses a white light emitting device comprising a substrate, and a layered body (see FIG. 1) that contains a reflective electrode, a first organic EL layer emitting first color light, a first transparent electrode, a second organic EL layer emitting second color light different from the first color light, and a second transparent electrode in this order, wherein the reflective electrode and the second transparent electrode are of the same polarity as one another, and the first transparent electrode is of the opposite polarity thereto.

In all of the methods disclosed in Japanese Unexamined Patent Application Publication No. 2003-45676, and Japanese Patent Nos. 3366401 and 3189438, the light emitting layers or light emitting units are connected in series in order to obtain white light and thus, the driving voltage needs to be increased. The increase in the voltage for driving the light emitting device may cause breakdown of the driver IC, which is undesirable in practical application. Therefore, there are demands for development of an organic EL light emitting device that can emit white light and yet can be driven with a low voltage.

Japanese Unexamined Patent Application Publication No. 2004-327248 discloses an organic EL light emitting device that emits white light or multicolor light without an increase in driving voltage by laminating a plurality of organic EL layers that are connected in parallel. FIG. 1 shows a lamination structure of an organic EL device that is a structure in the present invention and at the same time a structure disclosed in Japanese Unexamined Patent Application Publication No. 2004-327248. In manufacturing a passive matrix type organic EL device with this structure, reflective electrode 312, first transparent electrode 330, and second transparent electrode 322 must be patterned in a configuration of strips. In the electrodes shown in FIG. 1, the row of strips of reflective electrode 312 needs to be arranged parallel to the row of strips of second transparent electrode 322, and the row of strips of first transparent electrode 330 needs to be arranged orthogonal to the rows of strips of reflective electrode 312 and second transparent electrode 322.

FIG. 2 shows a structure generally employed at present of an organic EL device, in which separation walls 28 are provided for isolation between upper electrodes 27. The structure having separation walls 28 is effective for patterning electrodes of a device composed with a series connection in the direction of lamination. But the structure can hardly be applied to the lamination structure composed with a parallel connection as disclosed in Japanese Unexamined Patent Application Publication No. 2004-327248. The reason for this is because, in the process to form second organic EL layer 402 on the row of strips of first transparent electrode (intermediate electrode) 330 separated by separation walls 28 and to form second transparent electrode 322 across separation walls 28, the height of separation walls 28 is a relatively large value of from 2 to 10 μm for isolation of upper electrodes 27, and separation walls 28 divide the second transparent electrode 322 with a thickness of 100 to 300 nm. Thus, a row of strips of second transparent electrode orthogonal to the rows of first transparent electrodes (intermediate electrodes) 330 cannot be formed. Moreover, it is extremely difficult, for forming second transparent electrode 322, to form separation walls for isolation of second transparent electrode 322 on the first transparent electrode after forming first transparent electrode 330.

The present invention is directed to overcoming or at least reducing the effects of one or more of the problems set forth above.

### SUMMARY OF THE INVENTION

It is therefore an object of the present invention to provide a method of manufacturing a passive matrix type, white light emitting organic EL device voltage in which two organic EL layers are stacked and connected in parallel without an increase in driving. The method allows electrodes to be formed readily.

The method of the invention manufactures a white light emitting organic EL device having at least a reflective electrode, a first organic EL layer that emits light in a first color, an intermediate electrode unit (first transparent electrodes are formed on its both surfaces), a second organic EL layer that emits light in a second color different from the first color, and a second transparent electrode in this order, the reflective electrode being of the same polarity as the second transparent electrode, and the intermediate electrode unit being of opposite polarity to the reflective electrode and the second transparent electrode. The method comprises steps of (1) preparing a first organic light emitting unit including the reflective electrode and the first organic EL layer, (2) preparing a second organic light emitting unit including the second transparent electrode and the second organic EL layer, (3) preparing an intermediate electrode unit including the first transparent electrode on both sides thereof, and (4) disposing the intermediate electrode unit between the first organic light emitting unit and the second organic light emitting unit such that each of the first organic EL layer and the second organic EL layer opposes the first transparent electrode.

Two organic EL layers connected in parallel can be formed readily, and a device without an increase in driving voltage can be formed by the method comprising steps (1) through (4).

Advantageously in step (4), the first organic EL layer, the second organic EL layer, or both layers make contact with the first transparent electrodes through a metallic thin film(s). The metallic thin film sandwiched by the organic EL layer and the first transparent electrode improves electrical contact between the organic EL layer and the first transparent electrode of the intermediate electrode unit.

Advantageously, a micro resonant cavity selectively transmitting red color light is composed of the reflective electrode in the side of the first organic EL layer and a part of the first transparent electrode of the intermediate electrode unit in the side of the first organic EL layer. The resonator selectively transmits red color light to improve intensity and color purity of the red color light emission that is included in the white light.

In steps (1) and (2), each of the first organic EL layer and the second organic EL layer is divided into a plurality of areas each constituting a pixel and being isolated from one another. This structure is advantageous to impede electrical leakage between pixels.

In order to form the isolated areas of pixels, it is preferable in step (1) that the reflective electrode is formed of strips on a substrate, a first interlayer insulation film is formed in areas excepting areas of the pixels, and the first organic EL layer is formed by depositing organic material on the areas of pixels with a mask covering the areas excepting the areas of pixels on the substrate. It is also preferable in step (2) that the second transparent electrode is formed of strips on another substrate, a second interlayer insulation film is formed in areas excepting areas of the pixels, and the second organic EL layer is formed by depositing organic material on the areas of pixels with a mask covering the areas excepting the areas of pixels on the substrate. It is further preferable in step (4) that the intermediate electrode unit is disposed between the first organic light emitting unit and the second organic light emitting unit such that each area of pixel of the first organic EL layer opposes a corresponding area of pixel of the second organic EL layer.

According to the invention, a white light emitting device is readily formed without increase in driving voltage.

### BRIEF DESCRIPTION OF THE DRAWINGS

The foregoing advantages and features of the invention will become apparent upon reference to the following detailed description and the accompanying drawings, of which:

FIG. 1 schematically shows a basic structure of an organic EL device obtained by a manufacturing method according to the present invention;

FIG. 2 schematically shows a structure of an organic EL device having separation walls that is generally employed at present; and

FIGS. 3(a), 3(b), 3(c) show schematic construction of an example of a white light emitting organic EL device made by a manufacturing method according to the invention.

### DETAILED DESCRIPTION OF SPECIFIC EMBODIMENTS

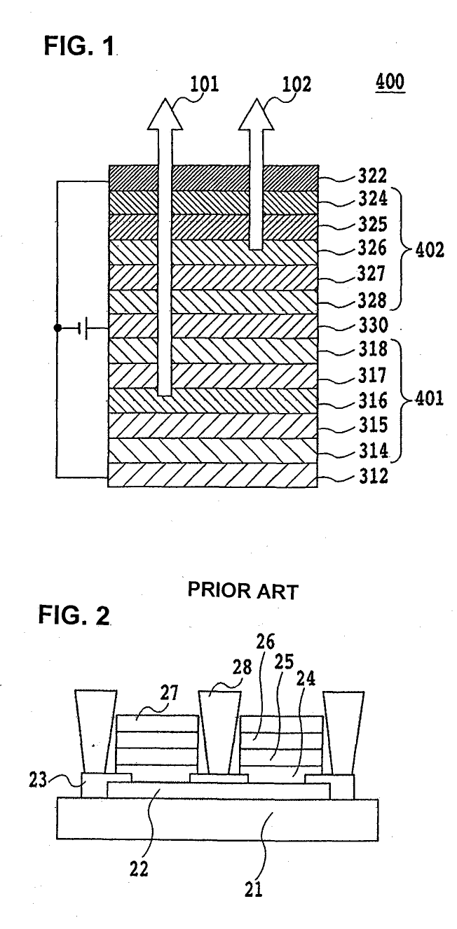

Now some preferred embodiments according to the present invention will be described. FIG. 1 schematically shows lamination structure 400 that is a basic structure of an organic EL device manufactured by the method of the invention. Lamination structure 400 has two light emitting parts on a substrate (not shown) including first organic EL layer 401, first transparent electrode (intermediate electrode) 330, second organic EL layer 402, and second transparent electrode 322 sequentially formed on reflective electrode 312. The first organic EL layer and the second organic EL layer emit light of first color 101 and light of second color 102 different from the first color, respectively.

Each of first organic EL layer 401 and second organic EL layer 402 includes at least organic light emitting layer 316, 326, and if necessary, electron injection layer 314, 324, electron transport layer 315, 325, hole transport layer 317, 327, and/or hole injection layer 318, 328. Specifically, a layer construction is selected from the following layer structures:

(a) Organic light emitting layer

(b) Hole injection layer/organic light emitting layer

(c) Organic light emitting layer/electron injection layer

(d) Hole injection layer/organic light emitting layer/electron injection layer

(e) Hole injection layer/hole transport layer/organic light emitting layer/electron injection layer

(f) Hole transport layer/organic light emitting layer/electron transport layer

(g) Hole injection layer/hole transport layer/organic light emitting layer/electron transport layer/electron injection layer

Here, an electrode that acts as an anode is connected to an organic light emitting layer, a hole transport layer, or a hole injection layer, and an electrode that acts as a cathode is connected to an organic light emitting layer, an electron transport layer, or an electron injection layer.

It is preferable from the view point of improvement in the electron injection efficiency to provide at least an electron injection layer.

In lamination structure 400 of FIG. 1, reflective electrode 312 is a cathode for first organic EL layer 401, first transparent electrode (intermediate electrode) 330 is a common anode for first organic EL layer 401 and second organic EL layer 402, and second transparent electrode 322 is a cathode for second organic EL layer 402.

Lamination structure 400 is manufactured by the following method in the invention:

(1) A first organic light emitting unit having reflective electrode 312 and first organic EL layer 401 on a substrate (not shown in FIG. 1) is prepared.

(2) A second organic light emitting unit having second transparent electrode 322 and second organic EL layer 402 on a substrate (not shown in FIG. 1) is prepared.

(3) Intermediate electrode unit 3300 having a first transparent electrode on both surfaces of a substrate (not shown in FIG. 1) is prepared.

(4) The intermediate electrode unit is sandwiched between the first organic light emitting unit and the second organic light emitting unit such that first organic EL layer and second organic EL layer oppose the first transparent electrode. The first organic light emitting unit, the intermediate electrode unit, and the second organic light emitting unit are stacked and arranged to fabricate a lamination body that is a white light emitting organic EL device. The lamination body is sealed and connected to a driver circuit to operate the white light emitting organic EL device. Here, the word “oppose” is used to include the case where the organic EL layer and the first transparent electrode are directly joined electrically, and also to include the case where the two are joined through a conductive film such as a metallic thin film.

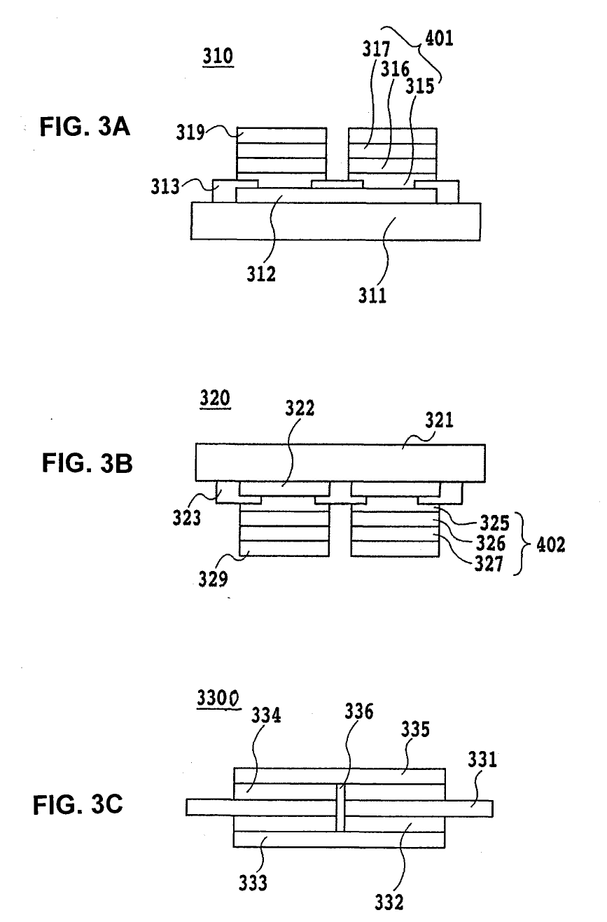

FIGS. 3(a), 3(b), and 3(c) show an embodiment of schematic construction of parts of a white light emitting organic EL device manufactured by the method of the invention, in which FIG. 3(a) shows an embodiment of first organic light emitting unit 310, FIG. 3(b) shows an embodiment of second organic light emitting unit 320, and FIG. 3(c) shows an embodiment of intermediate electrode unit 3300.

FIG. 3(a) is a partial sectional view of a first organic light emitting unit showing a cross-section including a reflective electrode extending in parallel to the plane of the page and two pixel areas. First organic light emitting unit 310 comprises laminated layers of reflective electrode 312 of a high reflectivity metallic film formed on substrate 311 and first interlayer insulation film 313 defining the pixel area, and on these layers, first organic EL layer 401 and metallic thin film 319. First organic EL layer 401 comprises at least electron transport layer 315, first organic light emitting layer 316, and hole transport layer 317 laminated sequentially.

FIG. 3(b) is a partial sectional view of a second organic light emitting unit showing a cross-section including two second transparent electrode films extending in the direction perpendicular to the plane of the page and two pixel areas. Second organic light emitting unit 320 comprises laminated layers of second transparent electrode 322 of transparent conductive material formed on substrate 321 and second interlayer insulation film 323 defining the pixel area, and on these layers, second organic EL layer 402 and metallic thin film 329. Second organic EL layer 402 comprises at least electron transport layer 325, second organic light emitting layer 326, and hole transport layer 327 laminated sequentially.

FIG. 3(c) is a partial sectional view of an intermediate electrode unit showing a cross-section including a through-hole and two pixel areas. The intermediate electrode unit 3300 comprises parts 333 and 335 of a first transparent electrode made of transparent conductive films formed on both surfaces of substrate 331 through barrier layers 332, 334. The two parts of the first transparent electrode are electrically connected by a conductor filled in through-hole 336.

Organic EL layers 401 and 402 shown in FIGS. 3(a) and 3(b), have the layer construction (f) shown previously. The organic EL layer can further comprise, if necessary, a hole injection layer and an electron injection layer. It is preferable to have at least an electron injection layer from the viewpoint of improvement in electron injection efficiency. Transparent electrodes 322, 333, 335 are preferably amorphous film of transparent conductive material such as IZO (indium zinc oxide) or ITO (indium tin oxide).

The following describes methods of fabricating organic light emitting units 310, 320 and intermediate electrode unit 3300.

First organic light emitting unit 310 can be fabricated for example, by the following procedure. First, a metal film is formed on cleaned substrate 311 by means of evaporation, sputtering, or the other technique, and patterned by photo-etching into strips, to obtain reflective electrode 312. Substrate 311 can be of glass, or a polymer material such as polycarbonate, polyethylene terephthalate, or polyethylene naphthalate. Substrate 311, when made of a polymer material, can be rigid or flexible. A material for the metal film can be a high reflectivity metal such as Al, Ag, No, W, Ni, or Cr, or an amorphous alloy such as NiP, NiB, CrP, or CrB. On patterned reflective electrode 312, first interlayer insulation film 313 is formed on the whole surface of the substrate excepting pixel areas. The interlayer insulation film can be formed using an organic material such as photoresist, or an inorganic material such as SiOx, SiNx or the like, for example. Using a mask having openings at pixel areas that are defined by first interlayer insulation film 313, organic materials are evaporated masking the parts excepting the pixel areas to deposit first organic EL layer 401 with a configuration of islands. The planar shape of the organic EL layer for each pixel is approximately square or rectangular.

Materials in the layers of first organic EL layer 401 are not limited to a special material but can be selected from known materials. An electron injection layer (not shown in the figure) can be formed using an alkali metal compound such as LiF. Electron transport layer 315 can be formed using Alq3 and an alkali metal such as Li can be doped therein. A material for organic light emitting layer 316 is selected corresponding to the desired hue. To obtain light emission in blue to blue-green color, useful materials include fluorescent brightening agents such as benzothiazole, benzoimidazole, and benzoxazole; and styryl benzene compounds, and aromatic dimethylidyne compounds. Useful host materials include aluminum chelate, 4,4′-bis(2,2′-diphenylvinyl), 2,5-bis(5-tert-butyl-2-benzoxazolyl)-thiophene (BBOT), and biphenyl (DPVBi). Blue color dopant can be 0.1 to 5 wt % of perylene, 2,5,8,11-tetra-t-butyl perylene (TBP), 4,4′-bis[2-{4-(N,N-diphenylamino)phenyl}vinyl]biphenyl (DPAVBi). Red color dopant can be 0.1 to 5 wt % of 4-(dicyanomethylene)-2-methyl-6-(p-dimethylaminostyryl)-4H-piran, 4,4-difluoro-1,3,5,7-tetraphenyl-4-bora-3a,4a-diaza-s-indacene, propane dinitrile (DCJT1), and Nile Red. A hole transport layer 317 can be formed using α-NPD, and a Lewis acid compound such as F4-TCNQ can be doped therein.

An organic EL layer with a configuration of islands is usually formed by a vacuum evaporation method using a mask. Alternatively, as disclosed in Japanese Unexamined Patent Application Publication No. H9-167684 and corresponding U.S. Pat. No. 5,688,551, a close-spaced deposition technique can be employed, in which a donor sheet with previously formed organic EL material is disposed close-spaced over a substrate and a heat source such as laser is irradiated to the desired areas to deposit the organic EL material on the substrate.

Thickness of the layers in first organic EL layer 401 can be appropriately determined considering the driving voltage and transparency. The thicknesses are usually in the range of 20-80 nm for hole transport layer 317, 20-40 nm for organic light emitting layer 316, 20-40 nm for electron transport layer 315, and 0.5-5 nm for an electron injection layer (not shown in the figure), although they are not limited to these ranges.

Metallic thin film 319 is formed on the top of the organic EL layer in the configuration of islands with a rectangular shape. The metallic thin film can be formed by vacuum evaporation employing a mask evaporation technique (evaporation is done masking the areas excepting the area to be evaporated) or by the close-spaced evaporation technique mentioned above. This metallic thin film is effective to improve contact with the first transparent electrode on the intermediate electrode unit. It is advantageous, in combination of metallic thin film 319 and part 333 of the first transport electrode, to compose a micro resonant cavity that selectively transmits specific light, for example red color light. Specifically, the micro resonant cavity is composed of a laminated structure of the reflective electrode, the first organic EL layer, the metallic thin film (which is a half mirror), and the first transparent electrode. Provision of a resonator that selectively transmits light at a specific wavelength improves light intensity and color purity of the specific light.

Second organic light emitting unit 320 can be fabricated for example, by the following procedure. First, a transparent conductive film is formed on cleaned substrate 321 by means of evaporation, sputtering or another technique, and patterned by photo-etching into strips to obtain second transparent electrode 322. Substrate 321 can be of glass, or a polymer material such as polycarbonate, polyethylene terephthalate, or polyethylene naphthalate. Substrate 321 when made of a polymer material can be rigid or flexible. A material for the transparent conductive film can be a transparent conductive metal oxide selected from ITO, tin oxide, indium oxide, IZO, zinc oxide, zinc-aluminum oxide, zinc-gallium oxide, or these oxides with a dopant of iron or antimony. On patterned second transparent electrode 322, second interlayer insulation film 323 is formed on the whole surface of the substrate excepting pixel areas. This interlayer insulation film, like the first interlayer insulation film, can be formed using an organic material such as photoresist, or an inorganic material such as SiOx, SiNx or the like, for example. Using a mask having openings at pixel areas that are defined by second interlayer insulation film 323, organic materials are evaporated masking the parts excepting the pixel areas to deposit second organic EL layer 402 with a configuration of islands. The planar shape of the organic EL layer for each pixel is approximately square or rectangular.

Materials in the layers of second organic EL layer 402 also are not limited to a special material but can be selected from known materials. Electron transport layer 325 can be formed using Alq3 and an alkali metal such as Li can be doped therein. The second organic EL layer emits light in a second color (102 in FIG. 1) different from the light of the first color (101 in FIG. 1). A material for second organic light emitting layer 326 is selected corresponding to the desired hue from the materials mentioned for the first organic light emitting layer. White light can be obtained from the light in a first color and the light in a second color in combination of two complementary colors of blue and red, blue and yellow, or blue-green and red, or in combination of three color light of green color in one layer and blue and red colors in the other layer.

Hole transport layer 327 can be formed using α-NPD, and a Lewis acid compound of F4-TCNQ can be doped therein. Thickness of the layers in second organic EL layer 402 also can be appropriately determined considering the driving voltage and transparency. The thicknesses are usually in the range of 20-80 nm for hole transport layer 327, 20-40 nm for organic light emitting layer 326, and 20-40 nm for electron transport layer 325, although they are not limited to these ranges. Metallic thin film 329 is formed on the top of the organic EL layer in the configuration of islands by the mask evaporation or the close-spaced evaporation technique.

Intermediate electrode unit 3300 has parts 333 and 335 of the first transparent electrode formed in a pattern of strips on substrate 331 through barrier layers 332 and 334. A material generally used for substrate 331 is a plastic film with a thickness in the range of 50 to 500 μm exhibiting transparent and relatively high heat resistance. Preferable materials include PC (polycarbonate), PET (polyethylene terephthalate), PES (polyether sulfone), PEN (polyethylene naphthalate), and PO (polyolefin). Useful material for substrate 331 is not limited to these materials but a film based on a multilayered resin film can also be used for substrate 331.

The barrier layer can be obtained by depositing SiOx or SiNx by means of a CVD method, for example. Thickness of the barrier layer is preferably in the range of 200 to 500 nm. The first transparent electrode can be obtained by depositing ITO or IZO by means of a sputtering method, for example. Thickness of the first transparent electrode is preferably in the range of 100 to 300 nm.

Before forming the layer of first transparent electrode in a pattern of strips on a film of substrate 331, through-holes 336 are formed in substrate 331 by means of laser beam irradiation or mechanical drilling. In the process of forming transparent electrode 333, 335, the material for the transparent electrode deposited on front and back surfaces of substrate 331 simultaneously enters into the surface of the through-holes, and the electrode materials on both surfaces come in contact with one another. Thus, the front part and the back part of the first transparent electrode are electrically connected and are of the same polarity. Although the through-holes can be formed at any place, they are preferably located at places that do not interfere with pixel areas.

Intermediate electrode unit 3300 formed as described above is disposed between first organic light emitting unit 310 and second organic light emitting unit 320, and the three units are bonded in a dry nitrogen atmosphere in a glove box (both oxygen and moisture concentration are controlled at most 10 ppm) to complete a white light emitting organic EL device. The units are so arranged that the layers and electrodes in the units construct the lamination structure of FIG. 1. Intermediate electrode unit 3300 is sandwiched by first organic light emitting unit 310 and second organic light emitting unit 320 and the three units are stacked, such that the first organic EL layer and the second organic EL layer are arranged so they oppose at every pixel and face the first transparent electrode. When the organic light emitting unit has a metallic thin film on its organic EL layer, the organic EL layer connects to the first transparent electrode through this metallic thin film.

The present invention will be further described hereinafter referring to specific embodiment examples.

### Example 1

A first light emitting section was formed with a pixel arrangement of pixel dimensions of 0.148 mm×0.704 mm and a gap between pixels of 0.130 mm on a first glass substrate 311 with a dimension of 500 mm×500 mm×0.50 mm by a fabrication method shown below.

First, a high reflectivity electrode of aluminum 100 nm thick was deposited on the whole substrate surface by an evaporation method and then polished. After applying a resist material “OFRP-800” (a product of Tokyo Ohka Kogyo Co., Ltd.) on the aluminum film, reflective electrode 312 that became a cathode was obtained by patterning the aluminum film by means of a photolithography method into a pattern of strips with a width of 0.204 mm, a gap of 0.074 mm, and a thickness of 100 nm.

Using a positive type photoresist WIX-2A (a product of Nippon Zeon Co., Ltd.), interlayer insulation film 313 having a thickness of 1 μm was formed on the reflective electrode, the insulation film having openings of 0.148×0.704 mm at pixel areas. The edge of interlayer insulation film 313 had an acute angle with respect to the substrate.

Subsequently, the substrate having reflective electrode 312 and interlayer insulation film 313 formed thereon was installed in a resistance heating evaporation apparatus. Using a mask having openings of 0.148×0.704 mm corresponding to subpixel areas, electron transport layer 315, organic light emitting layer 316, and hole transport layer 317 were deposited without releasing the vacuum. The vacuum chamber for the deposition process was evacuated down to 1×10⁻⁴ Pa. Alq3 was deposited to a thickness of 20 nm to form electron transport layer 315.

Organic light emitting layer 316 was deposited to a thickness of 20 nm using a host material of 4,4′-bis(2,2′-diphenylvinyl)biphenyl (DPVBi) doped with 1 wt % of red color dopant 4-dicyanomethylene-2-methyl-6-p-dimethylaminostyryl-4H-piran (DCM). Hole transport layer 317 was formed by depositing α-NPD to a thickness of 20 nm. Then, metallic thin film 319 of aluminum 5 nm thick was formed without releasing the vacuum employing the similar mask deposition technique. Thus, a first organic light emitting unit was fabricated.

Then, a second light emitting section with the same pixel arrangement as in the first organic light emitting unit was formed on second glass substrate 321 having dimensions of 500 mm×500 mm×0.50 mm. The fabrication process is the same as that of the first organic light emitting unit except that reflective electrode 312 was replaced by second transparent electrode 322 with a configuration of strips parallel to the reflective electrode, and the red color dopant was replaced by 5 wt % of blue color dopant 4.4′-bis[2-{4-(N,N-diphenylamino)phenyl}vinyl]biphenyl (DPAVBi) for a guest material in organic light emitting layer 326.

Second transparent electrode 322 was formed as follows. First, an ITO film was deposited on the whole surface by means of a sputtering method, followed by polishing to form the transparent electrode film. After applying a resist material “OFRP-800” (a product of Tokyo Ohka Kogyo Co., Ltd.) on the ITO film, second transparent electrode 322 that became a cathode was obtained patterning the ITO film by means of a photolithography method into a pattern of strips with a width of 0.204 mm, a gap of 0.074 mm, and a thickness of 100 nm. Thus, a second organic light emitting unit was fabricated.

Intermediate electrode unit 3300 was fabricated using substrate 331 of a polyimide film with dimensions of 500 mm×500 mm×0.50 mm. Barrier layers 332, 334 of SiN film were formed on both surfaces of substrate 331 by sputtering. Through-holes 336 were formed through the substrate of polyimide film and the SiN film in the region between pixel areas using a KrF excimer laser under the conditions of a laser spot diameter of 50 μm and a laser output in the range of 100 mJ/pulse to 450 mJ/pulse.

Then ITO was deposited by sputtering on the whole area of the both surfaces of substrate 331 having the barrier layers formed thereon. In this process, the ITO entered from both surfaces into the inside face of through-holes 336 and achieved contact, so that the ITO on both surfaces was electrically connected. Then, a YAG laser was scanned on the ITO formed on both surfaces in the direction orthogonal to the strips of the reflective electrode to separate pixel areas from non pixel areas. Thus, first transparent electrode 333, 335 that became a row of anode elements was obtained in a pattern of strips having a width of 0.204 mm, a gap of 0.048 mm, and a thickness of 100 nm that locate on RGB subpixels.

The thus obtained first organic light emitting unit 310, second organic light emitting unit 320, and intermediate electrode unit 3300 were introduced in a glove box. Units 310, 320, 3300 were so arranged and stacked that every subpixel area of the first organic light emitting unit opposed a corresponding subpixel area of the second organic light emitting unit, and the strips of the first transparent electrode that became a row of anode elements were orthogonal to the strips of the reflective electrode and also orthogonal to the strips of the second transparent electrode, both sets of strips becoming a row of cathode elements. With first transparent electrode 333, 335 sandwiched by the metallic thin films 319 and 329, the three units were sealed off using a UV-hardening adhesive in a dry nitrogen atmosphere (in which both oxygen and moisture concentrations were not high than 10 ppm). The reflective electrode and the second transparent electrode of the obtained organic EL light emitting device were connected to a negative terminal of a power supply, and the first transparent electrode was connected to a positive terminal of the power supply. On application of a voltage, white light emission was obtained at a hue of (0.30, 0.33) with a broad emission spectrum in the visible light region.

### Example 2

A white light emitting organic EL device of Example 2 was manufactured in the same manner as in Example 1 except that:

(1) One wt % of coumarin 6, a green color dopant, was added, in replace of the red color dopant, into organic light emitting layer 316 of the first organic light emitting unit; and

(2) Organic light emitting layer 326 of the second organic light emitting unit was doped with, in place of 5 wt % of DPAVBi, a blue color dopant of 4,4′-bis[2-{4-(N,N-diphenylamino)phenyl}vinyl]biphenyl (DPAVBi) in an amount of 2.5 wt % with respect to the host material and a red color dopant of 4-dicyanomethylene-2-methyl-6-p-dimethylaminostyryl-4H-piran (DCM) in an amount of 0.2 wt % with respect to the host material. Organic light emitting layers 316 and 326 were deposited to a thickness of 20 nm.

On application of a voltage, white light emission was obtained at a hue of (0.32, 0.30) with a broad emission spectrum in the visible light region.

### Comparative Example 1

A light emission section was formed similarly to Example 1 with a pixel arrangement of pixel dimensions of 0.148 mm×0.704 mm and a gap between pixels of 0.130 mm on a glass substrate having dimensions of 500 mm×500 mm×0.50 mm. A first organic light emitting unit was fabricated by sequentially depositing a reflective electrode (a cathode) of aluminum strips with a width of 0.204 mm, a gap of 0.074 mm, and a thickness of 100 nm on the substrate, an interlayer insulation film having openings of 0.148 mm×0.704 mm on the reflective electrode (a cathode), an electron transport layer of Alq3 with a thickness of 20 nm, a light emitting layer 20 nm thick of DPVBi with 5 wt % of blue color dopant of DPAVBi, a hole transport layer 20 nm thick of α-NPD, and an aluminum thin film 5 nm thick. A second transparent electrode unit was fabricated by forming a transparent electrode (an anode) of IZO having a pattern of strips with dimensions of a width of 0.204 mm, a gap of 0.074 mm, and a thickness of 100 nm on a glass substrate having dimensions of 500 mm×500 mm×0.50 mm. Finally, the first organic light emitting unit and the second organic light emitting unit were bonded with a UV-hardening adhesive and sealed off. Thus, an organic EL device having a single blue light emitting organic EL layer was obtained.

### Comparative Example 2

An organic EL device of Comparative Example 2 was manufactured in the same manner as in Comparative Example 1 except that the dopant in the light emitting layer was changed to a blue color dopant DPAVBi in an amount of 2.5 wt % with respect to the host material and a red color dopant DCM in an amount of 0.2 wt %. The thickness of the light emitting layer was 20 nm.

Evaluation

Reflective electrode 312 and second transparent electrode 322 of Examples 1 and 2 were connected to a negative terminal of a power supply, and first transparent electrode 330 was connected to a positive terminal of the power supply. For Comparative Examples 1 and 2, the reflective electrode was connected to the negative terminal and the transparent electrode was connected to the positive terminal of the power supply. A voltage was applied to each of the organic EL light emitting devices and a brightness of 1,000 cd/m² of the light at a wavelength of 470 nm was measured. The driving voltages for the devices of Example 1 and Comparative Example 1 were 6.5 V, and the driving voltages for the devices of Example 2 and Comparative Example 2 were 6.7 V. These results demonstrated that organic EL devices manufactured by the method of the invention causes a plurality of organic EL layers to emit light without an increase of a driving voltage and produces white light.

The method of manufacturing a white light emitting organic EL device according to the present invention readily construct a white light emitting device that does not need an increase in a driving voltage.

Thus, a method of manufacturing a white light emitting organic el device has been described according to the present invention. Many modifications and variations may be made to the techniques and structures described and illustrated herein without departing from the spirit and scope of the invention. Accordingly, it should be understood that the methods and apparatus described herein are illustrative only and are not limiting upon the scope of the invention.

### DESCRIPTION OF SYMBOLS

310: first organic light emitting unit
311, 321: substrate
312: reflective electrode
313: first interlayer insulation film
323: second interlayer insulation film
314, 324: electron injection layer
315,325: electron transport layer
316: first organic light emitting layer
317, 327: hole transport layer
318, 328: hole injection layer
319, 329: metallic thin film
320: second organic light emitting unit
322: second transparent electrode
326: second organic light emitting layer
330: first transparent electrode (intermediate electrode)
3300: intermediate electrode unit
331: substrate
332, 334: barrier layer
333, 335: first transparent electrode formed on both surfaces of the intermediate electrode unit
336: through-hole

What is claimed is:

1. A method of manufacturing a white light emitting organic EL device having at least a reflective electrode, a first organic EL layer that emits light in a first color, an intermediate electrode unit, a second organic EL layer that emits light in a second color different from the first color, and a second transparent electrode in this order, the reflective electrode being of the same polarity as the second transparent electrode, and the intermediate electrode unit being of opposite polarity to the reflective electrode and the second transparent electrode, the method comprising:
(1) preparing a first organic light emitting unit including the reflective electrode and the first organic EL layer;
(2) preparing a second organic light emitting unit including the second transparent electrode and the second organic EL layer;
(3) preparing an intermediate electrode unit including a first transparent electrode on both sides thereof; and
(4) disposing the intermediate electrode unit between the first organic light emitting unit and the second organic light emitting unit such that each of the first organic EL layer and the second organic EL layer opposes the first transparent electrode.

2. The method of manufacturing a white light emitting organic EL device according to claim 1, wherein the first organic EL layer, the second organic EL layer, or both the first and second organic EL layers contact the first transparent electrode through a metallic thin film during the disposing of the intermediate electrode unit between the first organic light emitting unit and the second organic light emitting unit.

3. The method of manufacturing a white light emitting organic EL device according to claim 1, wherein a micro resonant cavity is composed of the reflective electrode and the first transparent electrode of the intermediate electrode unit that faces the first organic EL layer.

4. The method of manufacturing a white light emitting organic EL device according to claim 1, wherein in (1) and (2), each of the first organic EL layer and the second organic EL layer is divided into a plurality of areas each constituting a pixel, and the areas are isolated from one another.

5. The method of manufacturing a white light emitting organic EL device according to claim 4, wherein in (1), the reflective electrode is formed of strips on a substrate, a first interlayer insulation film is formed in areas excepting areas of the pixels, and the first organic EL layer is formed by depositing organic material on the areas of pixels on the substrate with a mask covering the areas excepting the areas of pixels.

6. The method of manufacturing a white light emitting organic EL device according to claim 3, wherein in (2), the second transparent electrode is formed of strips on a substrate, a second interlayer insulation film is formed in areas excepting areas of the pixels, and the second organic EL layer is formed by depositing organic material on the areas of pixels on the substrate with a mask covering the areas excepting the areas of pixels.

7. The method of manufacturing a white light emitting organic EL device according to claim 6, wherein in (4), the intermediate electrode unit is disposed between the first organic light emitting unit and the second organic light emitting unit such that each area of pixel of the first organic EL layer opposes a corresponding area of pixel of the second organic EL layer.
